(19) United States
(12) Patent Application Publication
(10) Pub. No.: US 2002/0092616 A1
(43) Pub. Date: Jul. 18, 2002

(54) APPARATUS FOR PLASMA TREATMENT USING CAPILLARY ELECTRODE DISCHARGE PLASMA SHOWER

(76) Inventor: SEONG I. KIM, NORTHVALE, NJ (US)

Correspondence Address: MORGAN LEWIS & BOCKIUS LLP, 1111 PENNSYLVANIA AVENUE NW, WASHINGTON, DC, 20004, US

(21) Appl. No.: 09/338,539

(22) Filed: Jun. 23, 1999

(51) Int. Cl. C23F 1/00; C23C 16/00

(52) U.S. Cl. 156/345.43; 118/723 E

(57) ABSTRACT

A plasma treatment apparatus for a workpiece includes a metal electrode, a capillary dielectric electrode having first and second sides and coupled to the metal electrode through the first side, wherein the capillary dielectric electrode has at least one capillary, a shield body surrounding the metal electrode and the first side of the capillary dielectric electrode, wherein the shield body has first and second end portions, and a gas supplier providing gas to the metal electrode.

### BACKGROUND OF THE INVENTION

1. Field of the Invention

The present invention relates to a plasma discharge apparatus, and more particularly to an apparatus for plasma treatment using capillary electrode discharge (CED) plasma shower. Although the present invention is suitable for a wide scope of applications, it is particularly suitable for plasma treatment of workpieces under an atmospheric pressure or high pressure, thereby providing virtually unrestricted applications regardless of the size of the workpieces.

2. Discussion of the Related Art

A plasma discharge has been widely used for treating surfaces of a variety of workpieces in many different industries. Particularly, a station for cleaning or etching electronic components, such as a printed circuit board (PCB), lead frame, microelectronic device, and wafer, has been employed in electronics industries since it provides advantages over the conventional chemical cleaning apparatus. For example, the plasma process occurs in a closed system instead of in an open chemical bath. Thus, the plasma process may be less hazardous and less toxic than the conventional chemical process. One example of a related background art plasma process and apparatus was disclosed in U.S. Pat. No. 5,766,404.

Another example of the related background art was disclosed in “Surface Modification of Polytetrafluoroethylene by Ar+ Irradiation for Improved Adhesion to Other Materials”, Journal of Applied Polymer Science, pages 1913 to 1921 in 1987, in which the plasma process was applied on the surfaces of plastic workpieces in an effort to improve wetability or bonding of the workpieces.

All of the background art plasma processes, however, have to be carried out inside a treatment chamber because the background art plasma processes can only be performed under vacuum condition. Thus, when a workpiece is too big to be treated in the chamber, the background art plasma process cannot be used to treat the workpiece. As a result, the background art plasma processes are very limited in applications.

### SUMMARY OF THE INVENTION

Accordingly, the present invention is directed to an apparatus for plasma treatment using capillary electrode discharge plasma shower that substantially obviates one or more of problems due to limitations and disadvantages of the related art.

Another object of the present invention is to provide an apparatus for plasma treatment using capillary electrode discharge plasma shower which can be applied in sterilization, cleaning, etching, surface modification, or deposition of thin film under a high pressure or an atmospheric pressure condition.

Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

To achieve the objects and in accordance with the purpose of the invention, as embodied and broadly described herein, a plasma treatment apparatus for a workpiece includes a metal electrode, a capillary dielectric electrode having first and second sides and coupled to the metal electrode through the first side, wherein the capillary dielectric electrode has at least one capillary, a shield body surrounding the metal electrode and the capillary dielectric electrode except for the second side of the capillary dielectric electrode, wherein the shield body has first and second end portions, and a gas supplier providing gas to the metal electrode.

In another aspect of the present invention, a plasma treatment apparatus for a workpiece includes a metal electrode, a capillary tube surrounded by the metal electrode, wherein the capillary tube has first and second end portions, a shield body surrounding the metal electrode and the capillary tube except for the second end portion of the capillary tube, and a gas supplier providing gas to the first end portion of the capillary tube.

In another aspect of the present invention, a plasma treatment apparatus for a workpiece includes a metal electrode having a middle portion and first and second ends, a capillary dielectric electrode surrounding at least the middle portion and the first end of the metal electrode and providing a plasma discharge from the first and second sides of the metal electrode, and a gas supplier providing gas to the third side of the metal tube.

In a further aspect of the present invention, a plasma treatment apparatus for treating a workpiece includes a dielectric body having first, second, and third sides, at least one pair of first and second capillary dielectric electrodes in the third side of the dielectric body facing the center of the dielectric body, wherein the first and second capillary dielectric electrodes are adjacent to each other, a metal electrode on the capillary including the third side of the dielectric body, and a gas supplier providing gas to the first or second side of the dielectric body.

It is to be understood that both the foregoing general description and the following detailed description are exemplary and explanatory only and are not restrictive of the invention as claimed.

### BRIEF DESCRIPTION OF THE DRAWINGS

The accompanying drawings, which are incorporated in and constitute a part of this specification, illustrate several embodiments of the invention and together with the description, serve to explain the principles of the invention.

FIG. 1 is a schematic cross-sectional view illustrating an apparatus for plasma treatment using a capillary electrode discharge (CED) plasma shower according to a first embodiment of the present invention.

FIG. 2 is a schematic cross-sectional view illustrating an apparatus for plasma treatment using the CED plasma shower according to a second embodiment of the present invention.

FIGS. 3A to 3C are schematic views of various CED plasma shower heads of the present invention.

FIG. 4 is a photograph illustrating the CED plasma formed in FIG. 1.

FIG. 5 is a photograph illustrating the CED plasma formed in FIG. 2.

FIG. 6 is a schematic cross-sectional view illustrating an apparatus for plasma treatment using the CED plasma shower according to a third embodiment of the present invention.

FIGS. 7A and 7B are photographs illustrating an example of a sterilization capability of the CED plasma treatment in the present invention.

FIGS. 8A to 8C are photographs illustrating another example of the sterilization capability of the CED plasma treatment in the present invention.

FIG. 9 is a photograph illustrating an application in sterilization for a human body.

### DESCRIPTION OF THE PREFERRED EMBODIMENTS

Reference will now be made in detail to the present preferred embodiments of the invention, examples of which are illustrated in the accompanying drawings. Wherever possible, the same reference numbers will be used throughout the drawings to refer to the same or like parts.

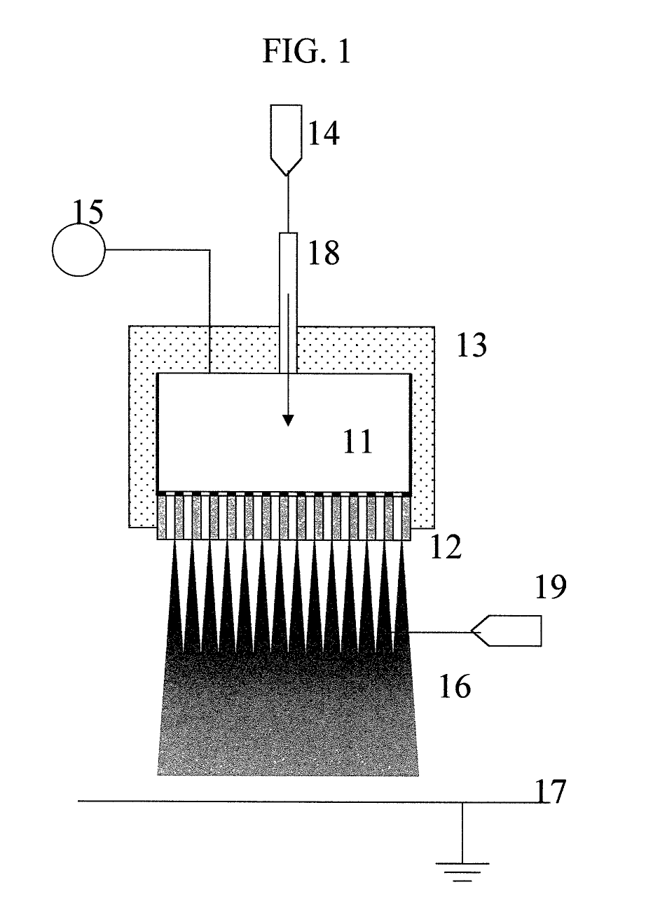

FIG. 1 is a schematic cross-sectional view illustrating an apparatus for plasma treatment using a CED plasma shower according to a first embodiment of the present invention. As shown in FIG. 1, an apparatus for plasma treatment using a CED plasma shower according to a first embodiment includes a metal electrode 11, a capillary dielectric electrode 12, a shield body 13, a gas supplier 14, a power supply 15, a gas tube 18, and an, auxiliary gas supplier 19.

Specifically, the metal electrode 11 is coupled to the power supply 15. Either a DC or a RF potential may be applied to the metal electrode. In the case where the RF potential is applied, it is preferably in the range of 10 KHz to 200 MHz.

The capillary dielectric electrode 12 has first and second insides and coupled to the metal electrode 11 through the first side of the capillary dielectric electrode 12. The capillary dielectric electrode 12 has at least one capillary. For example, the number of capillaries may range from one to thousands. A thickness of the capillary dielectric electrode 12 may be in the range of 2 mm to 300 mm. A diameter of each capillary is preferably in the range of 200 μm to 30 mm.

The metal electrode 11 is formed of a metal cylinder having one or more holes in the bottom surface that are substantially aligned with capillaries in the capillary dielectric electrode 12. One side of the capillary dielectric electrode 12 is coupled to the metal electrode 11 inside the shield body 13 while another side of the capillary dielectric electrode 12 is outside the shield body 13 and exposed to the workpiece.

A glow plasma discharge device using a perforated dielectric is disclosed in U.S. Pat. No. 5,872,426, which is incorporate herein by reference.

The shield body 13 surrounds the metal electrode 11 and the capillary dielectric electrode 12, so that it prevents unnecessary area from generating discharge. The shield body 13 is made of a dielectric material. A grip may be formed on the shield body 13, so that it can be held by a user for convenience.

The gas supplied with the metal electrode 11 passes through the capillary. Since a high electric field is maintained across the capillary dielectric electrode 12, a high density discharge beam is generated in the capillary. The gas may be a carrier gas or a reactive gas depending upon a specific application of the apparatus. For example, when the apparatus is used for thin film deposition or etching, an appropriate reactive gas is selected for a desired chemical reaction. Thus, a CED plasma discharge 16 are formed toward a workpiece 17.

Additionally, an auxiliary gas supplier 19 may be supplied to a space between the capillary dielectric electrode 12 and a workpiece 17 to be treated by plasma discharge.

The workpiece 17 to be treated by the apparatus for plasma treatment using the CED plasma shower (discharge) may act as a counter electrode. Thus, workpieces made of virtually any kind of material, such as metal, ceramic, and plastic, can be treated by the apparatus of the present invention. The workpiece 17 is generally at a ground potential with respect to the metal electrode 11.

The gas tube 18 made of a metal or a dielectric material is further coupled to the metal electrode 11, so that gas is supplied by the gas supplier 14 through the gas tube 18.

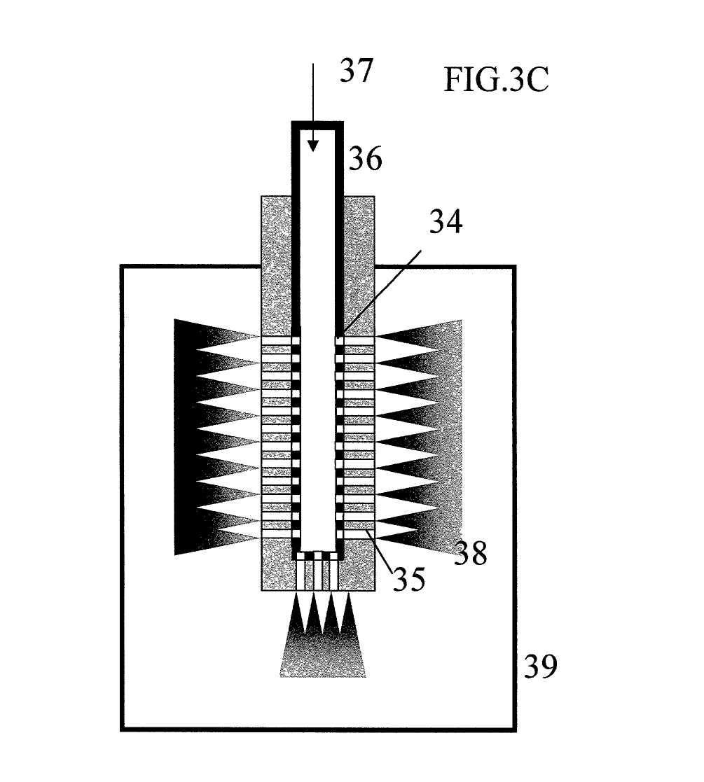

As an example, a photograph for the CED plasma generated according to the first embodiment of the present invention is shown in FIG. 4, wherein the apparatus has a plurality of capillary dielectric electrode.

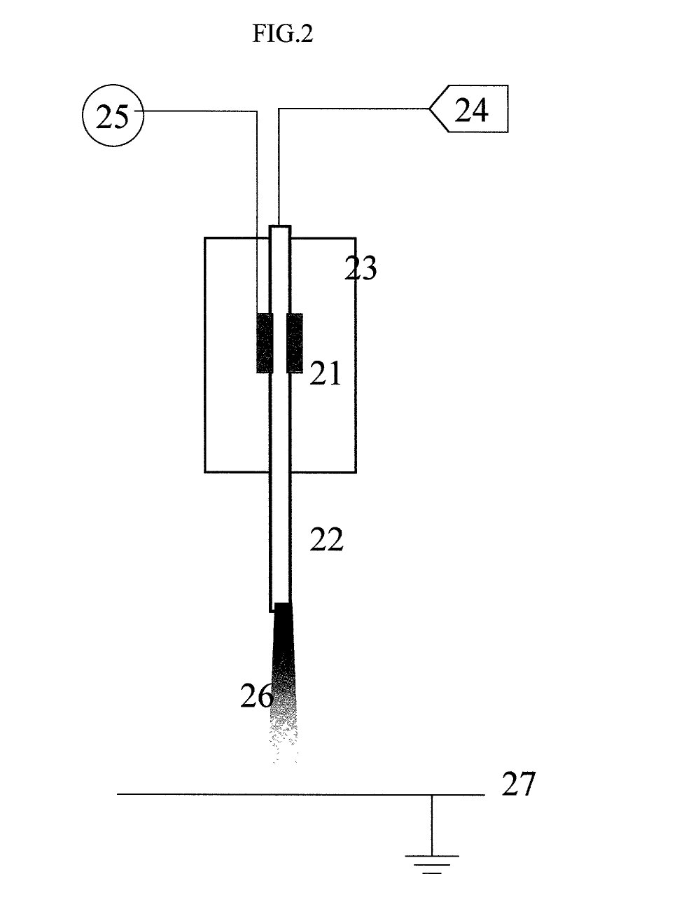

FIG. 2 is a schematic cross-sectional view illustrating an apparatus for plasma treatment using the CED plasma shower according to a second embodiment of the present invention. In FIG. 2, an apparatus for plasma treatment using the CED plasma shower according to a second embodiment of the present invention includes a metal electrode 21, a capillary tube 22, a shield body 23, a gas supplier 24, and a power supply 25.

The metal electrode 21 may be applied with a DC or a RF potential, and surrounds the middle portion of the capillary tube 22 which has first and second end portions. When a RF potential is applied, it is preferably in the range of 10 KHz to 200 MHz.

The first end portion of the capillary tube 22 is coupled to the gas supplier 24 while the second end portion is exposed for CED plasma shower 26. The shield body 23 covers both the metal electrode 21 and the capillary tube 22 except for the second end portion of the capillary tube 22, so that it suppresses a discharge generation except from the second end portion of the capillary tube 22. The shield body 23 may be formed of a dielectric material. A grip may be formed on the shield body 23 for convenience. A thickness of the capillary tube 22 is preferably in the range of 2 mm to 300 mm. A diameter of the capillary tube 22 is preferably in the range of 200 μm to 30 mm.

A carrier gas or a reactive gas may be supplied for the apparatus depending upon a specific application of the apparatus. Also, similar to the first embodiment, the workpiece 27 shown in FIG. 2 may act as a counter electrode and is generally at a ground potential with respect to the metal electrode 21. Using the apparatus of the present invention, a workpiece made of material such as metal, ceramic, or plastic may be treated.

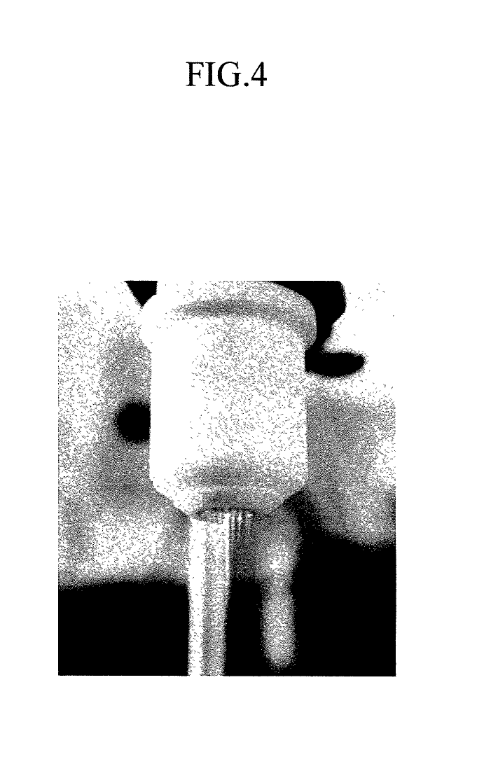

A CED plasma discharge generated from the apparatus according to the second embodiment is illustrated in FIG. 5.

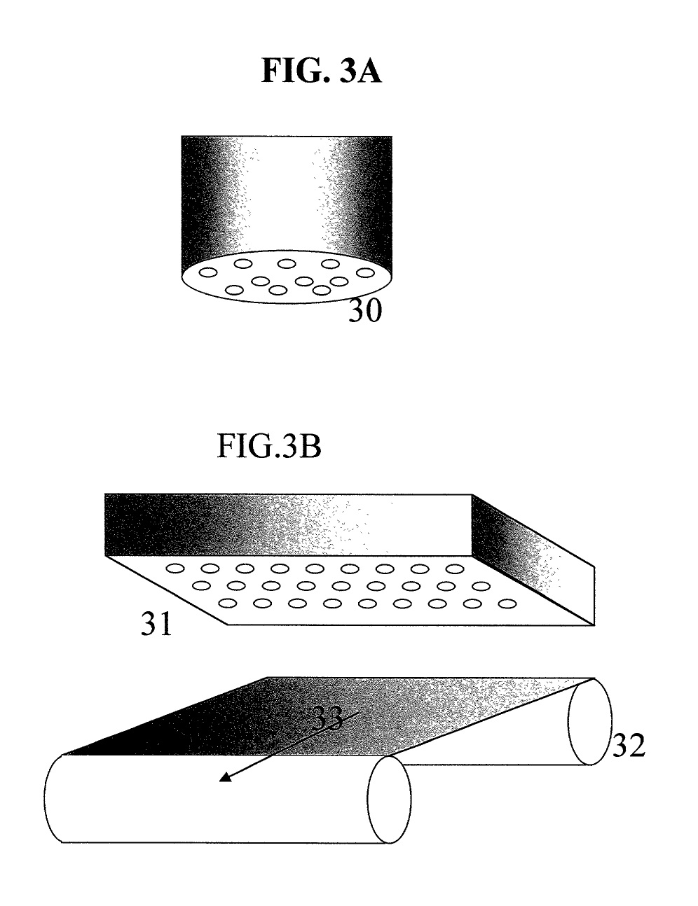

FIGS. 3A to 3C are schematic views of various shapes for an apparatus for plasma treatment using the CED plasma shower of the present invention. As shown in FIGS. 3A to 3C, a shape of the apparatus for plasma treatment may vary according to a shape of the workpiece. For example, circular shape apparatus 30 shown in FIG. 3A may be appropriate for a stationary and circular workpiece. On the other hand, a workpiece 33 like a plate or a roll of sheet may be more appropriately treated with a rectangular shape apparatus 41. Normally, since this kind of workpiece may not be treated at once, the workpiece is put in a linear motion with a linearly moving mechanism 32 as shown in FIG. 3B. A workpiece for a web process may also be treated by the rectangular shape apparatus with a linear motion mechanism.

A container such as a bottle may be treated using a cylindrical shape apparatus shown in FIG. 3C. A metal tube 37 has a plurality of holes on its entire surfaces except for portions for receiving gas and for being connected to the power source. The holes on the metal tube 37 match capillaries in a capillary dielectric electrode 35. Thus, the metal tube 37 acts as a metal electrode. The capillary dielectric electrode 35 surrounds and is connected to the metal tube 37 as shown in FIG. 3C. The capillary dielectric electrode 35 also functions as the shield body. As a result, a CED plasma discharge is emitted from the entire surfaces towards the inner walls of the workpiece to be treated as shown in FIG. 3C.

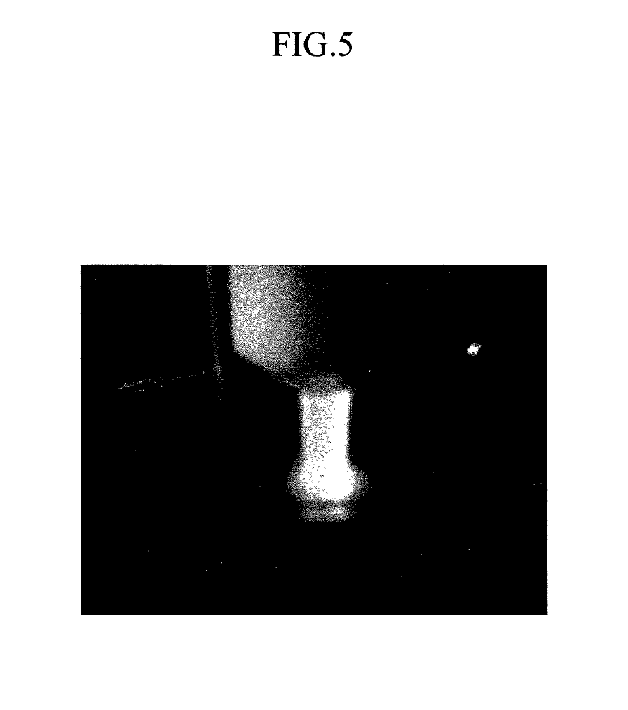

FIG. 6 is a schematic cross-sectional view illustrating an apparatus for plasma treatment using a CED plasma shower according to a third embodiment of the present invention. In this embodiment, the entire surface of a workpiece may be treated at once because the CED plasma discharge is emitted from a toroidal surface as shown in FIG. 6. An apparatus in the third embodiment includes a dielectric body 61, at least one pair of capillaries 62 in the dielectric body 61, a metal electrode 63 on the capillaries 62, and a power supply 64.

The dielectric body 61 has a cylindrical shape and has the capillaries 62 therein. Preferably, a thickness of the dielectric body 61 is in the range of 2 mm to 300 mm. Also, a diameter of the capillaries 62 in the range of 200 μm to 30 mm.

A gas supplier (not shown) may provide the apparatus with gas from either side of the apparatus. A workpiece 66 is positioned inside the apparatus, so that its entire surfaces can be treated at once, as shown in FIG. 6. When the workpiece acts as a counter electrode, all of the metal electrode 63 are supplied with a DC or a RF potential. In the case where the RF potential is applied, it is preferably in the range of 10 Khz to 200 MHz. Alternatively, in the case where the workpiece is not at a ground potential, each adjacent metal electrode is alternatively supplied with a ground potential and a DC/RF potential.

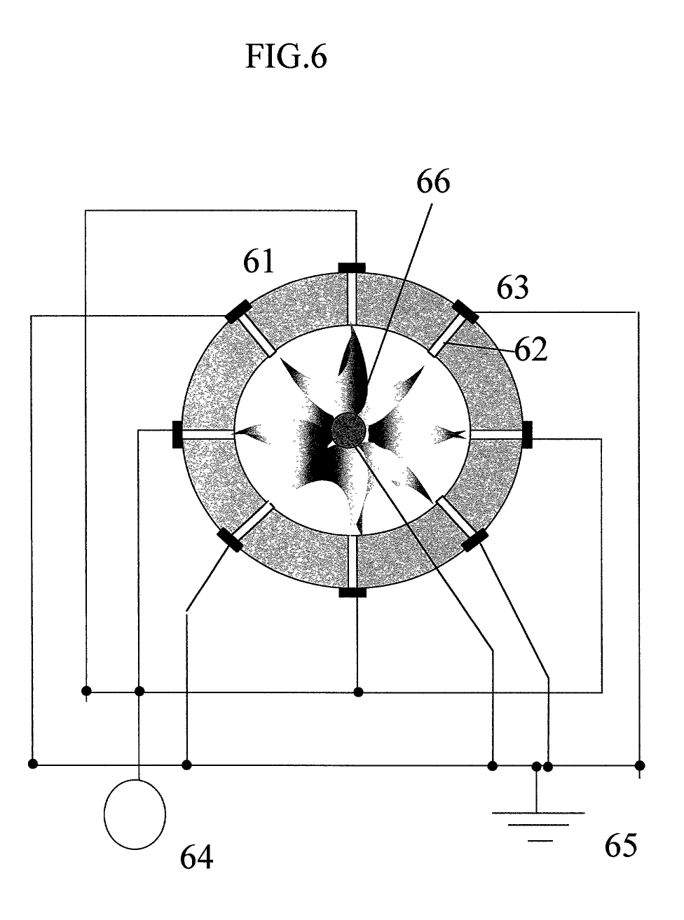

FIGS. 7A and 7B are photographs illustrating an example of a sterilization capability of the CED plasma treatment in the present invention. As shown therein, FIG. 7A illustrates that the first sample treated with the CED plasma shower of the present invention contains no bacteria growth. Conversely, a microbial growth is observed in the second sample treated with the conventional AC barrier type plasma, as shown in FIG. 7B. Thus, the treatment by the CED plasma shower of the present invention is much more effective than the conventional AC barrier type plasma treatment in sterilization.

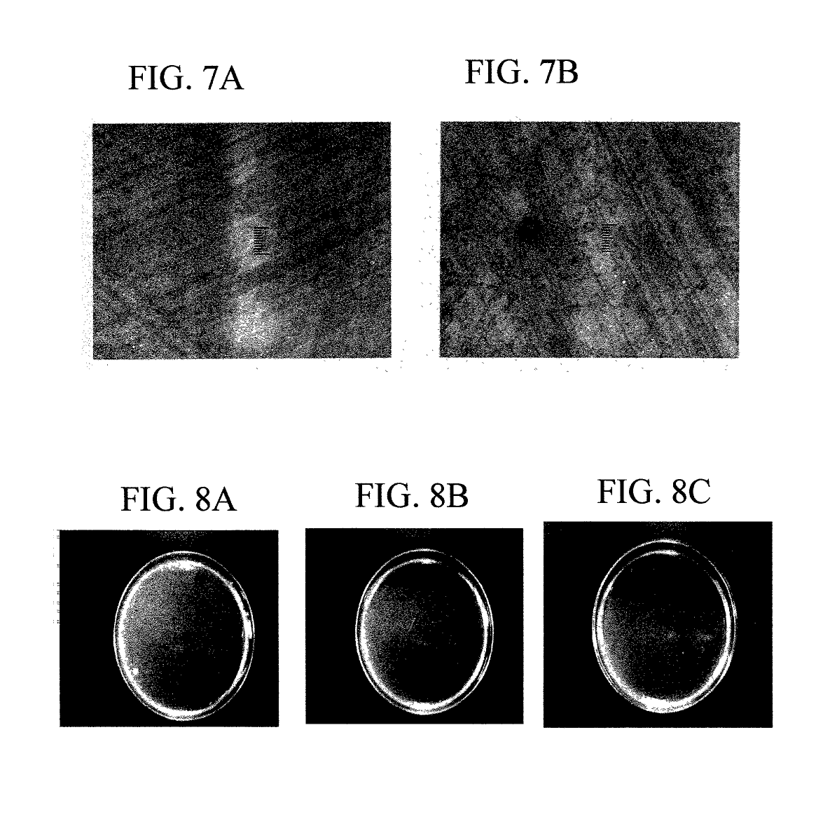

FIGS. 8A to 8C are photographs illustrating another example of the sterilization capability of the CED plasma treatment in the present invention. In this example, each of three identical soil samples is suspended in water and filtered to remove debris. A spore stain of the samples is smeared and fixed to a microscope slide in order to confirm that endospores are present in the samples. Thereafter, the first sample is treated with the CED plasma while the second sample is treated with the conventional AC barrier type plasma each for 6 minutes. The third sample is not treated by plasma at all. All samples are collected onto a cotton swab and soaked with sterile distilled water. The cotton swab was plunged into 1 ml of sterile distilled water. The swab was then streaked onto LB agar plates (yeast extract and typtone), and incubated at 37° C. for 18 hours. Then each sample is observed. The first sample treated with the CED plasma shower shows no lawn of microbial growth and only a single bacteria cell, as shown in FIG. 8A. Unlike the first sample, the second and third samples contain a partial or a full lawn of microbial growth, as shown in FIGS. 8B and 8C, respectfully.

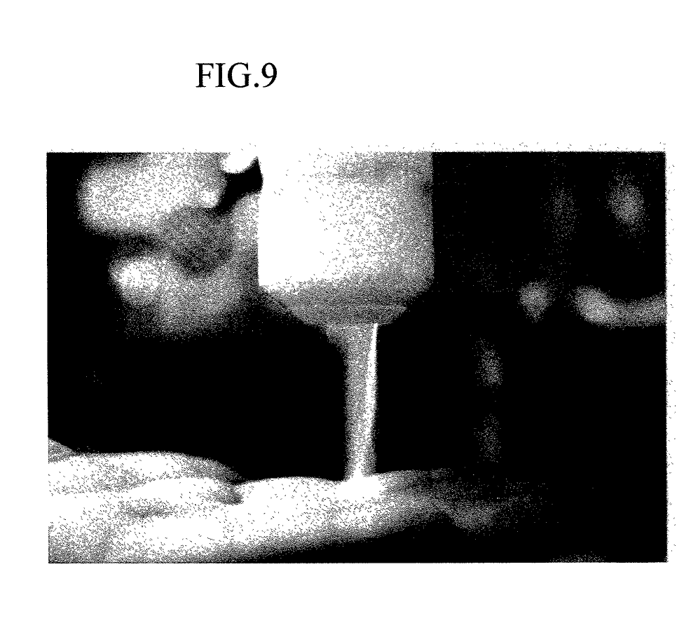

FIG. 9 is a photograph illustrating an application in sterilization for a human body. Since the plasma generated by the CED plasma shower of the present invention is non-thermal, it may be directly applied to a human body for sterilization and cleaning under the circumstances.

As described above, the apparatus for plasma treatment using capillary electrode discharge plasma shower has the following advantages over the conventional plasma treatment apparatus.

The CED shower of the present invention may be used for plasma treatment of workpieces under an atmospheric pressure or high pressure. Thus, it provides virtually unrestricted applications regardless of the size of the workpieces.

Moreover, in a sterilization process, the treatment by the CED plasma shower of the present invention is much more effective than the conventional AC barrier type plasma treatment.

It will be apparent to those skilled in the art that various modifications and variations can be made in the method and apparatus for treatment using capillary electrode discharge plasma shower of the present invention without departing from the scope or spirit of the invention. Thus, it is intended that the present invention cover the modifications and variations of the invention provided they come within the scope of the appended claims and their equivalents.

What is claimed is:

1. A plasma treatment apparatus for treating a workpiece, comprising:
a metal electrode;
a capillary dielectric electrode having first and second sides, the first side being coupled to the metal electrode wherein the capillary dielectric electrode has at least one capillary;
a shield body surrounding the metal electrode and the first side of the capillary dielectric electrode, wherein the shield body has first and second end portions; and
a gas supplier providing gas to the metal electrode.

2. The apparatus according to claim 1, further comprising a power supply providing a RF potential to the metal electrode in the range of 10 KHz to 200 MHz.

3. The apparatus according to claim 1, wherein the first end portion of the shield body has a cavity for carrying the gas.

4. The apparatus according to claim 1, wherein the second shield body has a circular shape or polygonal shape.

5. The apparatus according to claim 1, wherein the first end portion of the shield body includes a grip to be held by a user.

6. The apparatus according to claim 1, wherein the shield body includes a dielectric material.

7. The apparatus according to claim 1, wherein the metal electrode is supplied with either a DC or a RF potential.

8. The apparatus according to claim 1, wherein the workpiece acts as a counter electrode.

9. The apparatus according to claim 1, wherein the workpiece includes one of metal, ceramic, plastic, and human body.

10. The apparatus according to claim 1, wherein the workpiece is grounded with respect to the metal electrode.

11. The apparatus according to claim 1, wherein the shield body suppresses a plasma discharge except from the second side of the capillary dielectric electrode.

12. The apparatus according to claim 1, wherein the capillary dielectric electrode has a thickness in the range of 2 mm to 300 mm.

13. The apparatus according to claim 1, wherein the at least one capillary has a diameter in the range of 200 μm to 30 mm.

14. The apparatus according to claim 1, further comprising an auxiliary gas supplier providing auxiliary gas into a space between the second side of the capillary dielectric electrode and the workpiece.

15. The apparatus according to claim 1, wherein the metal electrode has a cylindrical shape.

16. The apparatus according to claim 1, wherein the metal electrode has at least one hole in a surface coupled to the first side of the capillary dielectric electrode.

17. The apparatus according to claim 16, wherein the at least one hole is substantially aligned with the at least one capillary of the capillary dielectric electrode.

18. The apparatus according to claim 1, further comprising a gas tube coupled to the first end portion of the shield body.

19. The apparatus according to claim 1, wherein the metal electrode has a hollow for accommodating the gas.

20. A plasma treatment apparatus for treating a workpiece, comprising:
a metal electrode;
a capillary tube surrounded by the metal electrode, wherein the capillary tube has first and second end portions;
a shield body surrounding the metal electrode and the capillary tube except for the second end portion of the capillary tube; and
a gas supplier providing gas to the first end portion of the capillary tube.

21. The apparatus according to claim 20, further comprising a power supply providing a RF potential to the metal electrode.

22. The apparatus according to claim 20, wherein the shield body has a first side having a circular shape or a polygonal shape and facing the workpiece.

23. The apparatus according to claim 20, wherein the shield body has a grip to be held by a user.

24. The apparatus according to claim 20, wherein the shield body includes a dielectric material.

25. The apparatus according to claim 20, wherein the metal electrode is supplied with either a DC or a RF potential.

26. The apparatus according to claim 20, wherein the workpiece acts as a counter electrode.

27. The apparatus according to claim 20, wherein the workpiece includes at least one of metal, ceramic, and plastic.

28. The apparatus according to claim 20, wherein the workpiece is grounded with respect to the metal electrode.

29. The apparatus according to claim 20, wherein the shield body suppresses a plasma discharge except from the second end portion of the capillary tube.

30. The apparatus according to claim 20, wherein the capillary tube has a thickness in the range of 2 mm to 300 mm.

31. The apparatus according to claim 20, wherein the capillary tube has a diameter in the range of 200 μm to 30 mm.

32. The apparatus according to claim 20, wherein the gas is supplied into the capillary tube through the first end portion of the capillary tube.

33. A plasma treatment apparatus for treating a workpiece, comprising:
a metal electrode having a middle portion and first and second ends;
a capillary dielectric electrode surrounding at least the middle portion and the first end of the metal electrode and providing a plasma discharge from the middle portion and first side of the metal electrode; and
a gas supplier providing gas to the second end of the metal electrode.

34. The apparatus according to claim 33, wherein the metal electrode has a cylindrical shape.

35. The apparatus according to claim 33, wherein the metal electrode has an inner space for accommodating the gas.

36. The apparatus according to claim 33, further comprising a power supply providing a RF potential to the metal electrode in the range of 10 KHz to 200 MHz.

37. The apparatus according to claim 33, wherein the metal electrode is supplied with either a DC or a RF potential.

38. The apparatus according to claim 33, wherein the workpiece acts as a counter electrode.

39. The apparatus according to claim 33, wherein the workpiece includes at least one of metal, ceramic, and plastic.

40. The apparatus according to claim 33, wherein the workpiece has an inner surface to be treated by a plasma discharge.

41. The apparatus according to claim 33, wherein the workpiece is grounded with respect to the metal electrode.

42. The apparatus according to claim 33, wherein the capillary dielectric electrode has a thickness in the range of 2 mm to 300 mm.

43. The apparatus according to claim 33, wherein the capillary dielectric electrode includes a plurality of capillaries each having a diameter in the range of 200 μm to 30 mm.

44. A plasma treatment apparatus for treating a workpiece, comprising:
a dielectric body having first, second, and third sides;
at least one pair of first and second capillary dielectric electrodes in the third side of the dielectric body facing the center of the dielectric body, wherein the first and second capillary dielectric electrodes are adjacent to each other;
a metal electrode on the capillary including the third side of the dielectric body; and
a gas supplier providing gas to the first or second side of the dielectric body.

45. The apparatus according to claim 44, wherein the dielectric body has a cylindrical shape.

46. The apparatus according to claim 44, wherein the number of the capillary is same as that of the metal electrode.

47. The apparatus according to claim 44, wherein the first and second capillary dielectric electrodes are connected to the power supply and a ground potential, respectively.

48. The apparatus according to claim 44, wherein the first capillary dielectric electrode is supplied with either a DC or a RF potential.

49. The apparatus according to claim 44, wherein the workpiece acts as a counter electrode.

50. The apparatus according to claim 44, wherein the workpiece includes at least one of metal, ceramic, and plastic.

51. The apparatus according to claim 44, wherein the workpiece is grounded with respect to the metal electrode.

52. The apparatus according to claim 44, wherein the capillary dielectric electrode has a thickness in the range of 2 mm to 300 mm.

53. The apparatus according to claim 44, wherein the capillary dielectric electrode includes a plurality of capillaries each having a diameter in the range of 200 μm to 30 mm.
